(19) United States
(12) Patent Application Publication
(10) Pub. No.: US 2003/0107051 A1
(43) Pub. Date: Jun. 12, 2003

(54) Super self -aligned heterojunction biplar transistor and its manufacturing method

(76) Inventors: Soo Gyun Park, Goonpo-shi (KR); Young Ho Lee, Gwang Myoung-shi (KR); Kang Hoon Seo, Goonpo-shi (KR); Jin Sung Choi, Gwacheon-shi (KR); Young Hwa Rho, Anyang-shi (KR)

Correspondence Address: ERIC B. MEYERTONS, CONLEY, ROSE & TAYON, P.C., P.O. BOX 398, AUSTIN, TX, 78767-0398, US

(21) Appl. No.: 10/294,046

(22) Filed: Nov. 14, 2002

(30) Foreign Application Priority Data
Dec. 10, 2001 (KR) 2001/77723

(51) Int. Cl. H01L 31/0328; H01L 31/0336; H01L 31/072; H01L 31/109

(52) U.S. Cl. 257/197

(57) ABSTRACT

A super self-aligned heterojunction bipolar semiconductor device and its manufacturing method are disclosed. The present invention provides a super self-aligned heterojunction bipolar transistor that may maintain the operational stability and the uniformity of a device, facilitate the manufacturing process, and reduce manufacturing time by employing a highly concentrated thick polysilicon film; and its manufacturing method. Also, the present invention provides a super self-aligned heterojunction bipolar transistor that may reduce noise by making the base resistance reduced by a highly concentrated thick polysilicon film, and may minimize the parasitic capacitance between a collector and a base and between a base and an emitter, and the parasitic resistance of a base, so as to realize high-speed operation of a device; and its manufacturing method.

### CROSS-REFERENCE TO RELATED APPLICATIONS

This application claims priority to Korean patent Application No. 2001/77723, filed Dec. 10, 2001.

### BACKGROUND OF THE INVENTION

1. Field of the Invention

The present invention relates to a super self-aligned heterojunction bipolar transistor (hereinafter “HBT”) including a Si/SiGe heterojunction base layer and its manufacturing method.

2. Description of the Related Art

In the communication technology field, semiconductor devices that can operate at high frequency are needed to achieve high-speed communications. To meet these needs, compound semiconductors such as GaAs, InP and SiGe have been developed and employed in high-speed communication devices. Among these compound semiconductors, devices using SiGe may be preferred to GaAs and InP for the capacity of SiGe for very large scale integration and high-speed performance.

SiGe devices have a hetero structure of Si, whose energy gap is 1.12 eV, and Ge, whose energy gap is 0.66 eV. Such a combination of different energy gaps may provide fast transition speed of electrons and a high efficiency of operation.

Further, by using SiGe for a base of a transistor, the injection efficiency of carrier into emitter may be improved such that high current gain is achieved. Since the doping level of a base is sufficiently improved and the width of the base may be narrowed, a device with better performance at high frequencies may be achieved. Moreover, cut-off frequency can be increased by reducing emitter-to-base diffusion time. In addition, by gradually increasing the concentration of Ge within a base, a device can be fabricated to have a much higher cut-off frequency.

Because the SiGe device has several advantages with respect to increasing the concentration of Ge within a base, several techniques to evaporate a high density SiGe layer have been developed. In particular, as is well known, since the lattice constant of Ge is larger than that of Si by 4%, when SiGe is grown on a semiconductor substrate, a lattice mismatch occurs between the substrate and SiGe, and consequently a compressive strain occurs. If a SiGe layer becomes thicker than a certain thickness, which is may be referred to as a “critical thickness,” the misfit energy increases such that the energy state reaches the point where dislocation of the alloy film can easily occur. This dislocation may adversely affect the performance of a device, and may cause leakage current and low breakdown voltage, particularly in a bipolar transistor.

As the concentration of Ge increases in a SiGe device, the critical thickness decreases due to a greater mismatch. For example, if the concentration of Ge is 50%, the critical thickness may be about 10 nm, which may be too thin a layer for a layer of a heterojunction bipolar transistor. By comparison, if the concentration of Ge is 10%, the critical thickness may be about 100 nm.

If the thickness of a base is about 100 nm, the concentration of Ge may be up to 15-20%. However, if the concentration of Ge is further increased, a misfit strain may occur at the base of SiGe device, and the performance of an HBT may fall off.

Therefore, an HBT is required that has a high Ge concentration, but in which substantially no misfit dislocation occurs.

Several methods have been filed or patented based on the heterojunction bipolar transistor (SiGe HBT) techniques described above. These may include methods by IBM in the U.S., NEC and HITACHI in Japan, Temic in Germany, and ETRI in Korea. With regard to the structural characteristics of a SiGe HBT, a method used by NEC may be representative. In the NEC method, a SiGe base layer is formed using a selective crystal growth process. By contrast, a prior art method of ASB Inc. uses a conventional crystal growth process.

The method of NEC in Japan is described below and represented in FIG. 1.

FIG. 1 shows a heterojunction bipolar transistor that selectively grows a base layer containing SiGe at a device active region, and thereby self-aligns collector-base and emitter-base, respectively. The manufacturing process is as follows:

An implanted n+ type collector 2 is formed by ion-implanting n+ type dopant into a p− type semiconductor substrate 1. Collector layer 3 is evaporated on the front surface of substrate 1, on which the implanted collector 2 is to be formed. n+ type dopant is ion-implanted into a portion of collector layer 3 on which a collector semiconductor electrode will later be formed, so that collector sinker 4 is formed. Collector sinker 4 may connect the implanted collector 2 to the collector semiconductor electrode.

Subsequently, in order to electrically separate the transistor from neighboring transistors, collector layer 3 and substrate 1 are etched to form a trench. Then, device isolating trench 5 is formed by filling an insulator such as boron phosphorus silica glass (BPSG) into the etched trench. The BPSG insulator is made flat by chemical-mechanical polishing (CMP) so that the surface of isolating trench 5 becomes the same level as that of collector layer 3. On substrate 1, whereon the collector layer 3 and the isolating trench 5 are formed, a silicon oxide film is evaporated to form collector insulating film 6. A p+ type polycrystalline silicon is evaporated to form base semiconductor electrode 7. A silicon nitride film is evaporated to form emitter insulating film 8. Emitter insulating film 8 and base semiconductor electrode 7 are together etched so that collector insulating film 6 is exposed.

Thereafter, by means of evaporation of an insulating material and anisotropic etching, the exposed portion of collector insulating film 6, masked by first sidewall insulating film 9 that is on the sidewall of emitter insulating film 8 and base semiconductor electrode 7, is removed by a wet-etching process, and a portion of collector layer 3 thereunder is exposed. After the portion of collector layer 3 is exposed, the wet-etching continues for some time so that undercut 6a is formed to reach a predetermined region under p+ type polycrystalline base semiconductor electrode 7. n type intrinsic collector region 10 is formed by further ion-implanting n type dopant into a portion of collector layer 3 in the active device region (which is exposed through first insulation film 9) so that the cut-off frequency of the device increases in a high-current state. (See FIG. 1a.)

An extrinsic collector region of collector layer 3 is exposed by undercutting n type intrinsic collector region 10 and collector insulating film 6. Only on the extrinsic collector region, an intrinsic SiGe layer, a p+ type SiGe layer, and an intrinsic Si layer (that later forms emitter 13) are sequentially piled up to selectively grow single crystalline base layer 11. Under base semiconductor electrode 7, which is exposed due to the undercut collector insulating film 6, base connector 12 is grown of the same polycrystalline layer as base layer 11.

After base layer 11 is formed to a predetermined thickness, in order to ensure connection between base layer 11 and base connector 12, a silicon film is filled in between. The growth rate of a single crystalline silicon layer is controlled to be minimized, while the growth rate of a polycrystalline silicon layer is controlled to be maximized, so as to minimize excessive growth on the intrinsic silicon layer of base layer 11 (which will later form emitter 13).

Subsequently, an insulating material such as silicon nitride is evaporated and etched anisotropically so that a second sidewall insulating film 14 that extends from the first insulating film 9 to the inner region of the opening and contacts with a part of base layer 11 (specifically, emitter 13) is formed. Thereafter, a part of collector insulating film 6 covering collector sinker 4 is etched to expose collector sinker 4.

On part of base layer 11 (specifically, emitter 13), an emitter semiconductor electrode 15 is formed comprising n type polycrystalline silicon. On the region around the opening where the implanted collector 2 is connected, collector semiconductor electrode 16 is formed. Collector semiconductor electrode 16 is made out of the same n type polycrystalline silicon as emitter semiconductor electrode 15. Thereafter, dopant within emitter semiconductor electrode 15 is heat-treated and diffused so that an intrinsic Si layer of top of base layer 11 forms an n type emitter 13.

Using the above process, a super self-aligned transistor is formed. In this transistor, the collector-base region is proximate to the undercut and the selective base layer growth. The emitter-base region is proximate to first sidewall insulating film 9 and second sidewall insulating film 14, respectively self-aligned without using any extra mask. (See FIG. 1.b.)

In the case of the above-described NEC device, an undercut 6a is made at the collector insulating film beneath base semiconductor electrode 7 by wet-etching. The procedural stability and uniformity of this process may be extremely difficult to control. The collector-base parasitic junction capacitance may be greatly influenced by the length of the undercut. Therefore, the stability and the uniformity of performance of the device may suffer.

Moreover, because the base layer is grown by means of a selective crystal growth process only on the surface of the silicon collector layer, the doping concentration, the amount of Ge, and the thickness of the layer may vary greatly due to the loading effect, influenced by the concentration and the size of the collector layer exposed on the wafer. The pressure during the growth process may be lowered to reduce the influences of the loading effect. However, a lower pressure may slow the growth rate to an extent that throughput decreases.

Further, because base semiconductor electrode 7 (employing polycrystalline silicon) has a large resistance itself and because of parasitic resistance, there may be a limit to improvement in the operating speed (fₘₐₓ) of the device.

The technique of ASB Inc. is described below and represented in FIG. 2. FIG. 2 shows a heterojunction bipolar transistor employing a base ohmic electrode of titanium silicide on a selective crystal growth film and employing SiGe as a base.

Implanted collector 22 is formed by ion-implanting and diffusing n+ type dopant such as arsenic (As) or phosphorus (P) on a p− type semiconductor substrate 21. Silicon is grown on the substrate whereon the implanted collector has been formed to form a collector layer.

In the collector layer, collector insulating film (field oxide film) 23 is formed, by means of thermal oxidation process (LOCOS) except at the regions that will later be active collector region 25 and collector sinker 24. Using a photo mask that is open only at the region corresponding to the collector sinker 24, n+ type dopant, such as As or P, is doped and diffused by a heat treatment.

Base layer 26 is formed on the entire front side of substrate 21 whereon the active collector region 25, collector sinker 24, and collector insulating film 23 are formed. For a heterojunction bipolar transistor, base layer 26 is grown comprising a SiGe layer without dopant and a p+ type SiGe layer. When base layer 26 is grown out of SiGe, it is desirable that a Si seed layer is formed first and the base layer 26 next, so that the thickness of base layer 26 and the distribution and the doping concentration of Ge is uniform. Thus, base layer 26 has a multilayer structure of an intrinsic silicon layer (which is a seed layer), a base layer (comprising intrinsic SiGe and p+ type SiGe), and an intrinsic silicon layer (which will later be an emitter), which are grown upward in serial order. Base layer 26 is patterned employing a photomask that defines a base electrode region.

After base layer 26 is formed, a masking film that covers an active base region of base layer 26 and collector sinker 24 is formed. The masking film comprises at least one of silicon oxide and silicon nitride. While the masking film is in place the portion of base layer 26 outside the active base region is processed to form a first base semiconductor electrode 28a.

Second base semiconductor electrode 28b is selectively grown only on the exposed first base semiconductor electrode 28a. Second base semiconductor electrode 28b is doped with boron by an in-situ process. Thereafter, Ti and TiN are sequentially sputtered, heat treated and wet-etched to selectively form base ohmic electrode 29 only on the second base semiconductor electrode 28b. Base ohmic electrode 29 may comprise titanium silicide (TiSi₂). Insulator 27 may divide intrinsic base region from first base semiconductor electrode 28a.

If ohmic electrode 29 were formed directly on a thin base layer, agglomeration of the silicide might penetrate the thin base layer and contact active collector region 25 such that a Schottky junction would be formed between the base and the collector.

However, in the case of the ASB Inc. device, because the ohmic electrode 29 is not formed on the active base region (which is covered with the masking film), but is instead formed on the second base semiconductor electrode 28b, the thickness of the base layer 26 can be kept thin so that a high-speed operation can be realized.

Emitter insulating film 30 is formed by evaporating silicon oxide or silicon nitride on the entire surface of the substrate whereon base ohmic electrode 29 is formed. Then, using a photomask that defines an emitter region, emitter insulating film 30 and masking film covering the base beneath emitter insulating film 30 are etched so that an opening is made at the emitter region. Polycrystalline n+ type silicon is formed and patterned using a photo mask defining emitter semiconductor electrode 31. Thereafter, heat treatment is performed, during which n+ type dopant inside emitter semiconductor electrode 31 is diffused into the intrinsic layer on top of base layer 26 so as to produce emitter 32.

Protection film 33 is evaporated on the entire surface of the resulting substrate. Protection film 33 is an insulating material such as silicon oxide or silicon nitride. Protection film 33, emitter insulating film 30 and masking film may be etched as required to form a base contact window, an emitter contact window and a collector contact window.

After washing the surface using a standard washing process, a barrier metal comprising titanium (Ti) and titanium nitride (TiN) is formed, and aluminum (Al) or Al-1%Si metal is evaporated. A heat treatment and a patterning are performed to form base terminal 34, emitter terminal 35, and collector terminal 36.

The above-described method used for the ASB device differs from the selective crystal growth method used for the NEC device in that when the SiGe base layer is formed, the base layer is formed on the entire substrate, rather than a selective region. For this reason, the thickness of the base layer and the distribution and doping concentration of Ge can be uniformly maintained, and base layer 26 is formed regardless of irregularities in the silicon area that is exposed.

However, insulating material 27 and emitter 32 are not self-aligned structures. Because of the misalignment, parasitic resistance and parasitic capacitance may exist between the base and the collector. To inhibit such misalignment, some space margin is required. To secure the space margin, the area is enlarged, increasing base resistance. As a consequence, the noise characteristic may be degraded. In addition, a stable device may not be achieved because of the difficulty in setting up the process condition in view of the loading effect.

### SUMMARY OF THE INVENTION

It is, therefore, a primary object of the present invention to provide a super self-aligned heterojunction bipolar transistor and its manufacturing method that provides high speed operation with less noise, improved operational stability, and uniformity of devices.

In accordance with the present invention, there is provided a method of manufacturing a heterojunction bipolar transistor comprising: a) forming a sub-collector by ion-implanting dopant into a portion of a semiconductor substrate and diffusing it; b) forming a field insulating film by forming a collector layer on the entire surface of the semiconductor substrate and oxidizing a region except a active collector region and a collector sinker by a LOCOS method; c) ion-implanting dopant into the collector sinker using a photo mask, heat-treating; diffusing; and removing the collector sinker to have a predetermined thickness; d) forming a base electrode by evaporating a thermal oxidation film, a base electrode and a base electrode protection film on the entire surface of the field insulating film, the active collector region and the sinker protection film; e) exposing the active collector region and the sinker protection film by etching the base electrode, the base electrode protection film, and the thermal oxidation film in a predetermined pattern; f) forming an intrinsic collector by ion-implanting dopant into the active collector region and heat-treating; g) forming a SiGe base layer on the entire surface of the protection film, the intrinsic collector and the sinker protection film; h) forming a masking film by evaporating a buffer protection film on the entire surface of the SiGe base layer and dry-etching the buffer protection film; i) separating the base and the emitter by removing the masking film by wet-etching and forming a first sidewall film and a second sidewall film; j) forming an emitter electrode by removing the second sidewall film and the first insulating film by etching and evaporating polysilicon on the base layer; k) removing the base electrode protection film by dry-etching so as to expose the base electrode and evaporating a silicon oxide film so as to protect the emitter electrode from the damage by dry-etching when the emitter sidewall film is formed; l) forming an emitter sidewall film by evaporating a silicon nitride film or a silicon oxide film and dry-etching in a predetermined pattern; m) forming an ohmic electrode only on the emitter electrode and the base electrode by exposing the emitter electrode and the base electrode by wet-etching, heat-treating, sputtering titanium (Ti) and titanium nitride (TiN) and wet-etching; n) forming an emitter contact window, a base contact window and a collector contact window by evaporating silicon oxide or silicon nitride on the entire surface of the semiconductor substrate whereon the ohmic electrode is formed to form an insulating film and patterning the insulating film and the sinker protection film using a photo mask; and o) forming a base terminal, an emitter terminal and a collector terminal by cleaning the surface of the semiconductor substrate according to the standard cleaning process, forming barrier metal by sputtering titanium (Ti) and titanium nitride (TiN), evaporating a conductive metal, heat-treating and patterning.

In accordance with this present invention, there is provided a super self-aligned heterojunction bipolar transistor comprising: a) a sub-collector formed by ion-implanting dopant into a portion of a semiconductor substrate and diffusing it; b) a field insulating film formed by forming a collector layer on the entire surface of the semiconductor substrate and oxidizing the a region except the active collector region and the collector sinker, wherein dopant is ion-implanted into the collector sinker, and wherein the collector layer is heat-treated and the ions are diffused in the collector sinker; c) a sinker protection film formed by removing the collector sinker to a predetermined thickness and forming a film on the collection sinker; d) a thermal oxidation film formed on the entire surface of the field insulating film, the active collector region and the sinker-protection film; e) a base electrode formed on the entire surface of the thermal oxidation film with a predetermined thickness by in-situ method; wherein a base electrode protection film is formed on the base electrode with a predetermined thickness so as to protect the base electrode; f) an intrinsic collector formed by dry-etching the base electrode and the base electrode protection film in a predetermined pattern; wet-etching the thermal oxidation film so as to expose the active collector region and the sinker protection film; ion-implanting dopant into the active collector region; and heat-treating; g) a SiGe base layer formed by forming a silicon film on the entire surface of the base electrode protection film, the intrinsic collector and the sinker protection film h) a first sidewall film and a second sidewall film formed by removing a masking film by wet-etching, wherein the masking film is formed by dry-etching a buffer protection film formed on the entire surface of the SiGe base layer; and evaporating a silicon oxide film or a silicon nitride film to a predetermined thickness; i) an emitter electrode formed by removing the second sidewall film and the first sidewall film respectively by etching; evaporating polysilicon on the base layer; heat-treating; and patterning; j) an emitter sidewall film formed by exposing the base electrode by dry-etching; evaporating a film on the base electrode; heat-treating; and wet-etching; k) an ohmic electrode formed on the emitter electrode and the base electrode by sputtering titanium (Ti) and titanium nitride (TiN) in order on the emitter electrode and the base electrode, heat-treating, and wet-etching; l) an insulating film formed by evaporating silicon oxide or silicon nitride on the entire surface of the semiconductor substrate whereon the ohmic electrode is formed; m) a barrier metal formed by forming an emitter contact window, a base contact window and a collector contact window by patterning the insulating film and the sinker protection film using a photo mask; cleaning the surface of the semiconductor substrate; and sputtering titanium (Ti) and titanium nitride (TiN); and n) a base terminal, an emitter terminal, and a collector terminal provided by evaporating a conductive metal on the barrier metal, heat-treating and patterning.

### BRIEF DESCRIPTION OF THE DRAWINGS

These and other features, aspects, and advantages of preferred embodiments of the present invention will be more fully described in the following detailed description and the accompanying drawings, in which:

FIGS. 1a and 1b show cross-sectional views of a super self-aligned heterojunction bipolar transistor manufactured by prior art techniques;

FIG. 2 shows a cross-sectional view of another super self-aligned heterojunction bipolar transistor manufactured by prior art techniques; and

FIG. 3a to FIG. 3j show cross-sectional views representing the manufacturing process of a super self-aligned heterojunction bipolar transistor-in accordance with the present invention.

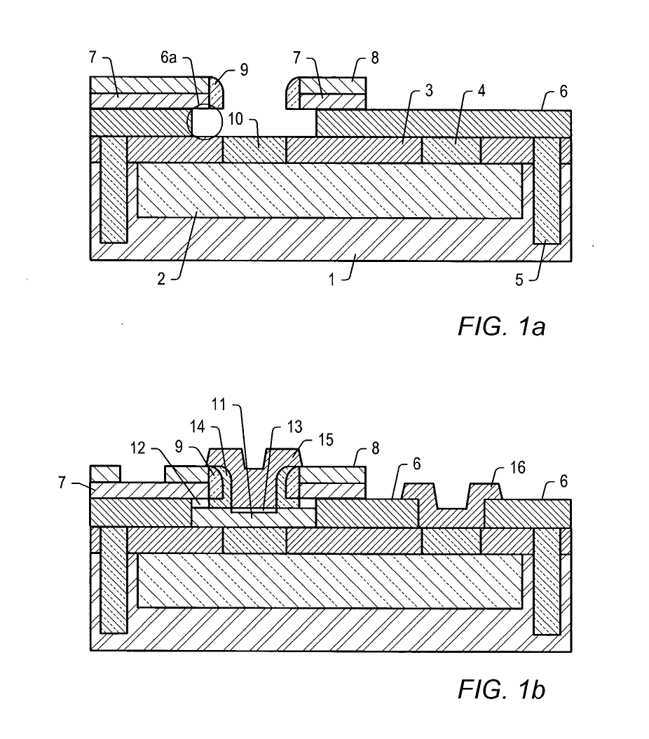

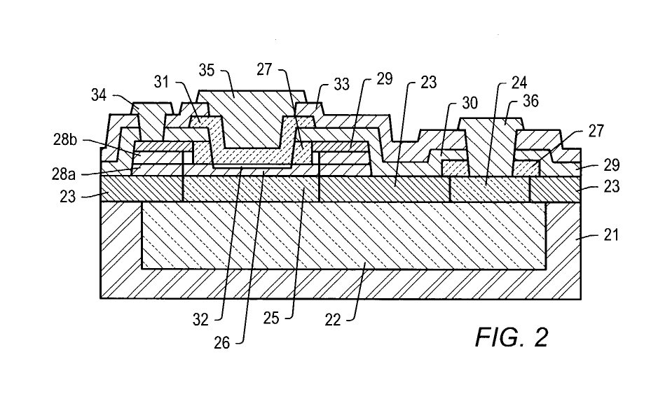

### DETAILED DESCRIPTION OF THE PREFERRED EMBODIMENTS

A heterojunction bipolar transistor and its manufacturing method according to this invention are further described herein.

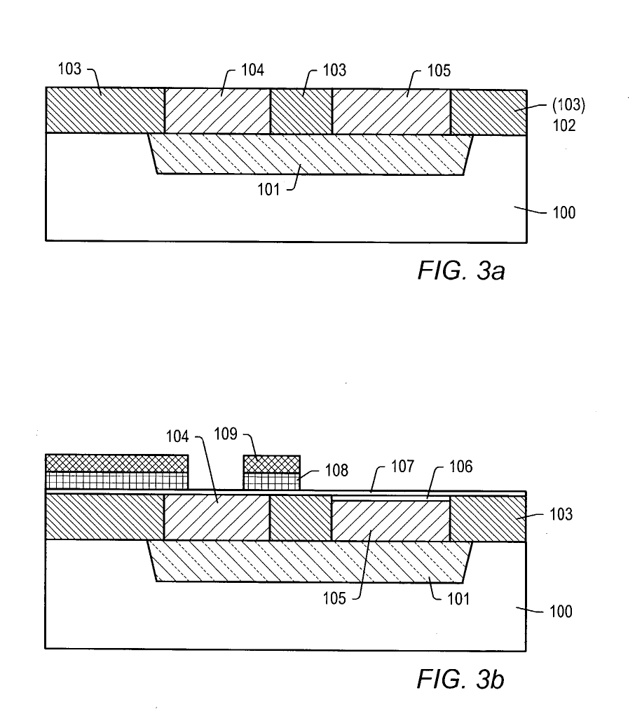

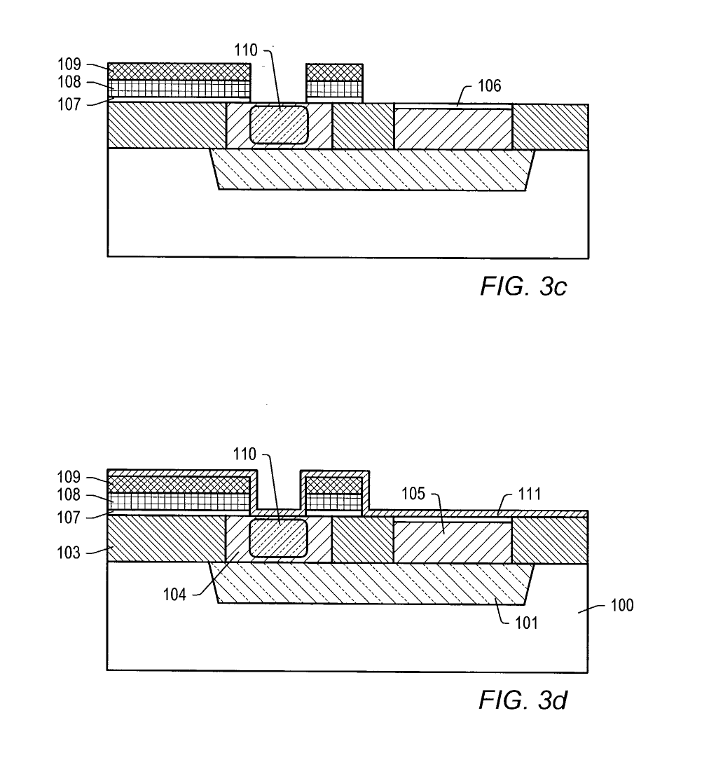

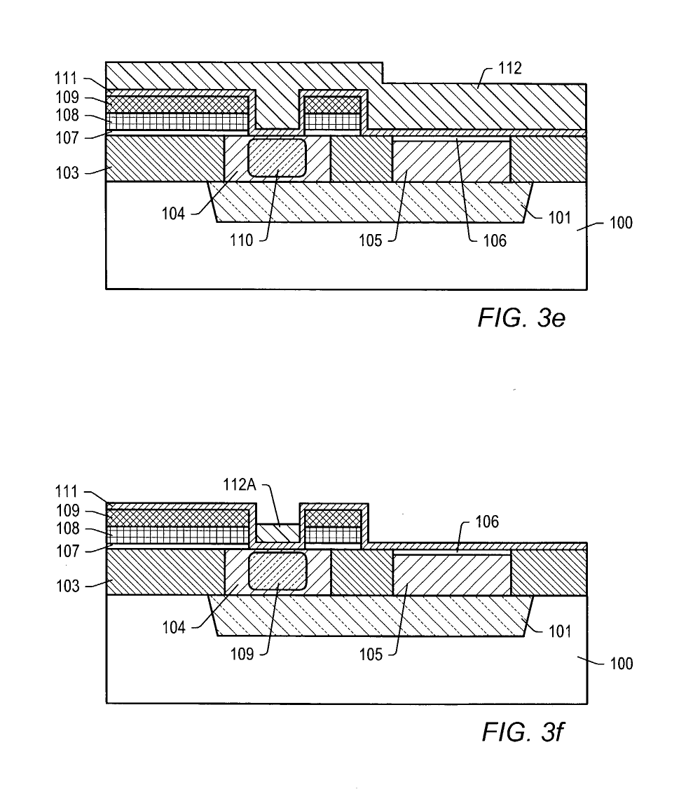

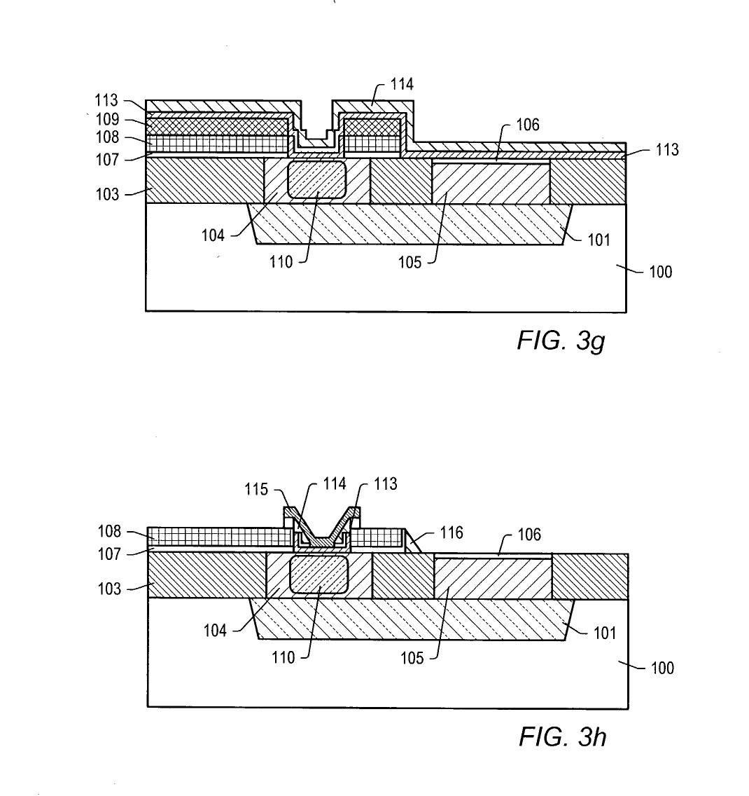

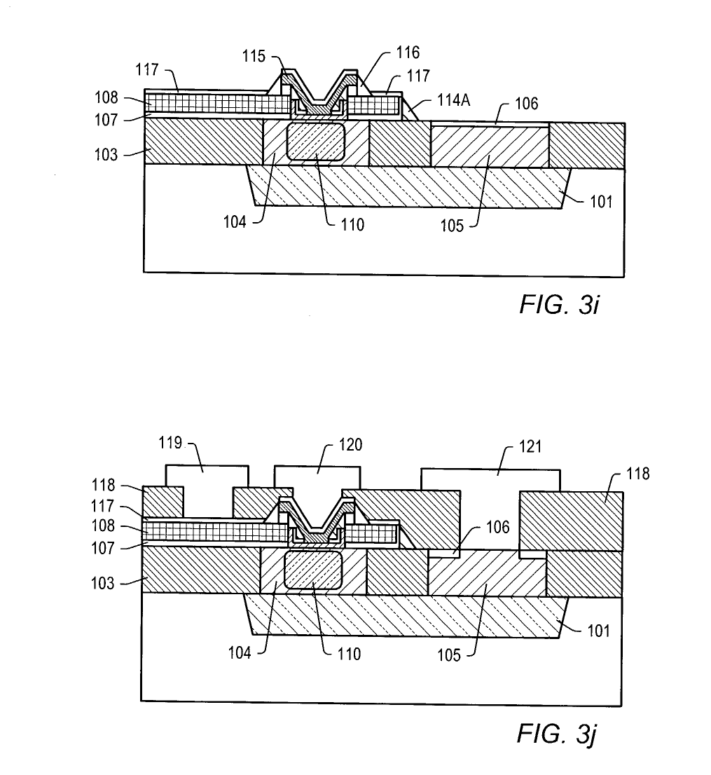

One embodiment of a manufacturing method according to this invention is discussed with reference to FIG. 3. First, a semiconductor substrate 100 may be prepared. Semiconductor substrate 100 may be a p-type semiconductor substrate. The resistivity of semiconductor substrate 100 may be over 50 Ω-cm. n+ type dopant such as arsenic (As) or stibium (antimony) (Sb) may be ion-implanted with a concentration of about 5×10¹⁹ cm⁻³ to about 1×10²⁰ cm⁻³ into a part of semiconductor substrate 100 and diffused so that sub-collector 101 is formed. Thereafter, collector layer 102 may be formed on the entire surface of semiconductor substrate 100. Collector layer 102 may be, for example, a silicon layer with a thickness of about 500 nm to about 1200 nm. Collector layer 102 may be formed by means of a thermal oxidation method.

Field insulating film 103 may be formed by employing a LOCOS method to collector layer 102 except at active collector region 104 and the region of collector sinker 105. Thereafter, n+ type dopant such as arsenic (As) or phosphorus (P) may be ion-implanted into said collector sinker 105 with a concentration of about 5×10¹⁹ cm⁻³ to about 1×10²⁰ cm⁻³. Collector layer 102 may be heat-treated and the implanted ions diffused. Subsequently, a part of the upper surface of collector sinker 105 may be removed by employing photoresist. (FIG. 3a)

Sinker protection film 106 may be formed on collector sinker 105 where the part of the upper surface of collector sinker 105 was removed. Thermal oxidation film 107, which may comprise a silicon oxide film, may be formed on the entire surface of field insulation film 103, active collector region 104, and sinker protection film 106 at a temperature of between about 900-1000° C. and heat treated. Thermal oxidation film 107 may have a thickness of about 20 nm to about 100 nm. Thereafter, base electrode 108, which may comprise polysilicon, may be evaporated by an in-situ process in which p+ type dopant such as boron (B) is doped into the entire surface of thermal oxidation film 107. Base electrode 108 may have a thickness of about 200 nm to about 600 nm. The concentration of dopant may be over 1×10¹⁹ cm⁻³. Base electrode protection film 109, which may comprise silicon nitride film or silicon oxide film, may be evaporated so as to protect base electrode 108. Base electrode protection film 109 may have a thickness of about 200 nm to about 600 nm. Subsequently, to expose a base and emitter region, thermal oxidation film 107 may be exposed by sequentially dry-etching base electrode 108 and base electrode protection film 109 using a photomask. (FIG. 3b)

Subsequently, thermal oxidation film 107 may be wet-etched by HF, NH₄F, or a mixture thereof. Active collector region 104 and sinker protection film 106 may be exposed. Thereafter, intrinsic collector 110 may be formed by ion-implanting n+ type dopant such as arsenic (As) or phosphorus (P) into active collector region 104 with a concentration of 1×10¹⁶ cm⁻³ to about 5×10¹⁸ cm⁻³. Active collector region 104 may be heat treated so that the cut-off frequency of the device increases. (FIG. 3c)

A silicon film, which may have a thickness of 10 nm to about 60 nm, may be formed on the entire surface of base electrode protection film 109, intrinsic collector 110, and sinker protection film 106. An intrinsic SiGe film, a p+ type extrinsic SiGe, and an intrinsic silicon film may be sequentially grown so that the SiGe base layer 111 is formed. Base layer 111 may have a thickness of about 50 nm to about 100 nm in total. The concentration of Ge may be in the range of 1 to about 20%. The doping concentration of p+ type dopant such as boron (B) may be in the range of 10¹⁹ cm⁻³ to about 3×10²⁰ cm⁻³. (FIG. 3d)

Subsequently, buffer protection film 112 may be evaporated on the entire surface of SiGe base layer 111 by a low pressure chemical vapor deposition (LPCVD) method. (FIG. 3e) Buffer protection film 112 may be dry-etched until the upper surface of base electrode 108 is reached so that masking film 112A is formed. (FIG. 3f)

The portion of base layer 111 that is not masked by masking film 112A may be removed by dry-etching. Then, masking film 112A may be removed by wet-etching, thereby exposing the remaining portion of base layer 111. Thereafter, by employing a low pressure chemical vapor deposition method (LPCVD), first sidewall film 113, which may comprise a silicon oxide film or a silicon nitride film with a thickness of about 50 nm about 300 nm, may be formed to separate base and emitter. Second sidewall film 114 may be formed by thickly evaporating a silicon oxide film or a silicon nitride film. The thickness of second sidewall film 114 may be about 200 nm to about 800 nm. First sidewall film 113 may inhibit damage to the surface of the emitter when the emitter is exposed.

Subsequently, second sidewall film 114 may be removed by dry-etching. First sidewall film 113 may be removed by wet-etching. Simultaneously, base electrode protection film 109 and sinker protection film 106 may be exposed.

Thereafter, emitter electrode 115 may be formed by evaporating n+ type polysilicon on the exposed portion of base layer 111. The junction between the base and the emitter may be formed by diffusing the n+ type dopant contained in emitter electrode 115 into base layer 111. Emitter electrode 115 may be patterned by using a photomask which defines the emitter electrode. Base electrode protection film 109 may be removed by dry-etching so that base electrode 108 is exposed. (FIG. 3h)

To form silicide ohmic electrode 117 on the electrodes of the emitter and the base, emitter sidewall film 116 may first be formed by evaporating a silicon nitride film or a silicon oxide film and dry-etching. Emitter sidewall film 116 may have a thickness of about 200 to about 1000 nm. Emitter sidewall film 116 may prevent the emitter electrode 115 from being damaged during dry-etching. The thickness of the silicon nitride film or silicon oxide film may vary according to the area of the exposed emitter so that the exposed emitter region is fully refilled. Emitter electrode 115 and base electrode 108 may be exposed by wet-etching.

Subsequently, ohmic electrode 117, which may comprise titanium silicide (TiSi₂), may be formed only on emitter electrode 115 and base electrode 108. Ohmic electrode 117 may be formed by sequentially sputtering titanium (Ti) and titanium nitride (TiN), heat-treating and wet-etching. The thickness of ohmic electrode 117 may be about 40 nm to about 60 nm. (FIG. 3i)

Insulating film 118 may be formed by evaporating silicon oxide or silicon nitride on the entire surface of the semiconductor substrate 100 whereon ohmic electrodes 117 of the base and the emitter are formed. Emitter contact window, base contact window, and collector contact window may be sequentially formed by patterning insulating film 118 and sinker protection film 106 using a photo mask. Thereafter, semiconductor substrate 100 may be washed according to a standard washing process. Base terminal 119, emitter terminal 120, and collector terminal 121 may be formed by evaporating a metal, heat-treating and patterning. In one embodiment, the metal of the terminals may be selected from a group consisting of aluminum (Al), aluminum-silicon (Al—Si), copper (Cu), and gold (Au). (FIG. 3j)

While the present invention has been described with reference to the illustrative embodiments, this description is not intended to be construed in a limiting sense. Numerous other arrangements may be readily devised by those skilled in the art that embody the principles of the invention and fall within its spirit and scope.

For example, in the above embodiment, the description of a p type semiconductor substrate and an n type dopant is not intended to be construed in a limiting sense, and numerous other arrangements are possible, for example, an n type semiconductor and a p type dopant.

While the present invention has been described in the above description the heterojunction bipolar transistor and its manufacturing method, in particular, an NPN type junction device and its manufacturing method, the description is not intended to be construed in a limiting sense. For example, the present invention can be applied to a PNP type junction device and its manufacturing method, or a BiCMOS (Bipolar CMOS) device and its manufacturing method, and so on.

Advantages of the present invention may include:

(1) According to the present invention, since the SiGe heterojunction bipolar transistor may be realized with a super self-aligned structure and a base layer may be formed by means of the entire surface crystal growth process, there may be an advantage that the uniformity of the device performance can be maintained.

(2) According to the present invention, since the process may be shortened by streamlining the mask alignment process, etc., there may be an advantage that manufacturing cost can be reduced.

(3) According to the present invention, since the base electrode may be formed using highly concentrated thick polysilicon, there may be advantages that the process condition can be easily set up and the time required for manufacturing can be shortened.

(4) According to the present invention, since the base electrode may be formed using highly concentrated thick polysilicon, and the noise may be reduced by reducing the space of the sidewall, thereby reducing the base resistance, and a titanium silicide film may also be applied to a base electrode and an emitter electrode, there may be an advantage that parasitic resistance and parasitic capacitance can be minimized, which may facilitate high speed operation of a device.

What is claimed is:

1. A method of manufacturing a heterojunction bipolar transistor comprising:
a) forming a sub-collector by ion-implanting dopant into a portion of a semiconductor substrate and diffusing it;
b) forming a field insulating film by forming a collector layer on the entire surface of the semiconductor substrate and oxidizing a region except at an active collector region and a collector sinker by a localized oxidation of silicon (LOCOS) method;
c) ion-implanting dopant into the collector sinker using a photo mask; heat-treating; diffusing; and removing the collector sinker to have a predetermined thickness; and forming a sinker protection film;
d) forming a base electrode by evaporating a thermal oxidation film, a base electrode, and a base electrode protection film on the entire surface of the field insulating film, the active collector region, and the sinker protection film;
e) exposing the active collector region and the sinker protection film by etching the base electrode, the base electrode protection film and the thermal oxidation film in a predetermined pattern;
f) forming an intrinsic collector by ion-implanting dopant into the active collector region and heat-treating;
g) forming a SiGe base layer on the entire surface of the protection film, the intrinsic collector and the sinker protection film;
h) forming a masking film by evaporating a buffer protection film on the entire surface of the SiGe base layer and dry-etching the buffer protection film;
i) separating the base and the emitter by removing the masking film by wet-etching and forming a first sidewall film and a second sidewall film;
j) forming an emitter electrode by removing the second sidewall film and the first insulating film by etching and evaporating polysilicon on the base layer;
k) removing the base electrode protection film by dry-etching so as to expose the base electrode; and evaporating a silicon oxide film so as to protect the emitter electrode from the damage by dry-etching when the emitter sidewall film is formed;
l) forming an emitter sidewall film by evaporating a silicon nitride film or a silicon oxide film and dry-etching in a predetermined pattern;
m) forming an ohmic electrode only on the emitter electrode and the base electrode by exposing the emitter electrode and the base electrode by wet-etching, heat-treating, sputtering titanium (Ti) and titanium nitride (TiN) and wet-etching;
n) forming an emitter contact window, a base contact window and a collector contact window by evaporating silicon oxide or silicon nitride on the entire surface of the semiconductor substrate whereon the ohmic electrode is formed to form an insulating film and patterning the insulating film and the sinker protection film using a photo mask; and
o) forming a base terminal, an emitter terminal and a collector terminal by cleaning the surface of the semiconductor substrate according to the standard cleaning process, forming barrier metal by sputtering titanium (Ti) and titanium nitride (TiN), evaporating a conductive metal, heat-treating and patterning.

2. The method according to claim 1, wherein the sub-collector is formed by ion-implanting dopant with a concentration of from about 5×10¹⁹ cm⁻³ to about 1×10²⁰ cm⁻³ into a portion of the semiconductor substrate having a resistivity larger than about 50/Ωcm, and diffusing the dopant.

3. The method according to claim 1, wherein the field insulating film is formed by oxidizing the collector layer formed on the entire surface of the semiconductor substrate except the active collector region and the collector sinker to a thickness of about 500 nm to about 1200 nm by a localized oxidation of silicon process (LOCOS) method.

4. The method according to claim 1, wherein the sinker protection film is formed by ion-implanting n+ type dopant with a concentration from about 5×10¹⁹ cm⁻³ to about 1×10²⁰ cm⁻³ into the collector sinker, heat-treating and diffusing the dopant, and removing an upper part of the collector sinker using photoresist.

5. The method according to claim 1, wherein the base electrode is formed by forming a thermal oxidation film comprising polysilicon with a thickness of about 20 nm-100 nm on the entire surface of the field insulating film, the active collector region and the sinker protection film at a temperature of between about 900-1000° C.; evaporating the base electrode comprising polysilicon with a thickness of about 200 nm to about 600 nm by doping p+ type dopant with a concentration higher than about 1×10¹⁹ cm⁻³ into the entire surface of the thermal oxidation film by in-situ method; evaporating the base electrode protection film comprising silicon nitride or silicon oxide with a thickness of about 200 nm to about 600 nm for protecting the base electrode; and removing the base electrode and the base electrode protection film by dry-etching using a photo mask.

6. The method according to claim 1, wherein the exposing step is performed by wet-etching the thermal oxidation film with HF, NH₄F or their mixture and exposing the active collector region and the sinker protection film.

7. The method according to claim 1, wherein the collector is formed by ion-implanting n+ type dopant with a concentration of from about 1×10¹⁶ cm⁻³ to about 5×10¹⁸ cm³ into the active collector region and heat-treating.

8. The method according to claim 1, wherein the base layer is formed by forming silicon layer on the entire surface of the base electrode protection film, the intrinsic collector, and the sinker protection film, and growing an undoped SiGe film, SiGe doped with p+ type dopant, and an undoped silicon film in order.

9. The method according to claim 8, wherein the SiGe base layer has a thickness of about 50 nm to about 100 nm.

10. The method according to claim 1, wherein the SiGe base layer has a thickness of about 50 nm to about 100 nm.

11. The method according to claim 1, wherein the concentration of Ge ranges from about 1% to about 20% and the doping concentration of dopant ranges from about 5×10¹⁸ cm³ to about 3×10²⁰ cm⁻³.

12. The method according to claim 8, wherein the concentration of Ge ranges from about 1% to about 20% and the doping concentration of dopant ranges from about 5×10¹⁸ cm⁻³ to about 3×10²⁰ cm⁻³.

13. The method according to claim 1, wherein the masking film is formed by evaporating the buffer protection film on the entire surface of the SiGe base layer by means of a low pressure chemical vapor deposition (LPCVD) method; and removing the buffer protection film by dry-etching so that the buffer protection film reaches an upper surface of the base electrode.

14. The method according to claim 1, wherein the base and the emitter are separated by removing an exposed portion of the base layer by dry-etching; removing the masking film by wet-etching; and evaporating the first sidewall film and the second sidewall film on the base layer using a low pressure vapor deposition (LPCVD) method.

15. The method according to claim 14, wherein the first sidewall film comprises a silicon oxide film or a silicon nitride film with a thickness of about 50 nm to about 300 nm.

16. The method according to claim 14, wherein the second sidewall film comprises a silicon oxide film or a silicon nitride film with a the thickness of the second sidewall film ranges from about 200 nm to about 800 nm.

17. The method according to claim 1, wherein the emitter electrode is formed by removing the second sidewall film by dry-etching; removing the first sidewall by wet-etching; and evaporating n+ type polysilicon on the base layer.

18. The method according to claim 16, wherein the emitter electrode is formed by diffusing n+ type dopant into the base layer to form a junction between the base and the emitter, and patterning the emitter electrode using a photo mask.

19. The method according to claim 1, wherein the emitter sidewall film is formed by removing the base electrode protection film by dry-etching; evaporating a silicon nitride film or a silicon oxide film with a thickness of about 200 nm to about 1000 nm on the surface of the emitter electrode and the base electrode; and dry-etching in a predetermined pattern.

20. The method according to claim 1, wherein the ohmic electrode is formed by exposing the emitter electrode and the base electrode by wet-etching; sputtering titanium (Ti) and titanium nitride (TiN) on the surface of the semiconductor substrate; heat-treating; and forming the ohmic electrode only on the emitter electrode and the base electrode by wet-etching.

21. The method according to claim 20, wherein the ohmic electrode is formed to have a thickness of about 40 nm to about 60 nm.

22. The method according to claim 1, wherein the ohmic electrode has a thickness of about 40 nm to about 60 nm.

23. The method according to claim 1, wherein the base contact window, the emitter contact window and the collector contact window are formed by forming the insulating film through evaporating silicon oxide or silicon nitride on the surface of the semiconductor substrate whereon the ohmic electrode is formed; and patterning the insulating film and the sinker protection film using a photo mask.

24. The method according to claim 1, wherein the base terminal, the emitter terminal and the collector terminal are formed by cleaning the surface of the semiconductor substrate by a standard cleaning process; forming barrier metal by sputtering titanium (Ti) and titanium nitride (TiN), evaporating a metal selected from the group consisting of aluminum (Al), aluminum-silicon (Al—Si), copper (Cu) and gold (Au), heat-treating; and patterning.

25. A super self-aligned heterojunction bipolar transistor comprising:
a) a sub-collector formed by ion-implanting dopant into a portion of a semiconductor substrate and diffusing it;
b) a field insulating film formed by forming a collector layer on the entire surface of the semiconductor substrate, and oxidizing a region except an active collector region and an collector sinker, wherein dopant is ion-implanted into the collector sinker, and wherein the collector layer is heat-treated and the ions are diffused in the collector sinker;
c) a sinker protection film formed by removing the collector sinker to a predetermined thickness and forming a film on the collector sinker;
d) a thermal oxidation film formed on the entire surface of the field insulating film, the active collector region and the sinker-protection film;
e) a base electrode formed on the entire surface of the thermal oxidation film with a predetermined thickness by in-situ method; wherein a base electrode protection film is formed on the base electrode with a predetermined thickness so as to protect the base electrode;
f) an intrinsic collector formed by dry-etching the base electrode and the base electrode protection film in a predetermined pattern; wet-etching the thermal oxidation film so as to expose the active collector region and the sinker protection film; ion-implanting dopant into the active collector region; and heat-treating;
g) a SiGe base layer formed on the entire surface of the base electrode protection film, the intrinsic collector and the sinker protection film;
h) a first sidewall film and a second sidewall film formed by removing a masking film by wet-etching, wherein the masking film is formed by dry-etching a buffer protection film formed on the entire surface of the SiGe base layer; and evaporating a silicon oxide film or a silicon nitride film to a predetermined thickness;
i) an emitter electrode formed by removing the second sidewall film and the first sidewall film respectively by etching; evaporating polysilicon on the base layer; heat-treating; and patterning;
j) an emitter sidewall film formed by exposing the base electrode by dry-etching; evaporating a silicon nitride film or a silicon oxide film on the base electrode; heat-treating; and wet-etching;
k) an ohmic electrode formed on the emitter electrode and an exposed portion of the base electrode by sputtering titanium (Ti) and titanium nitride (TiN) in order on the emitter electrode and the base electrode, heat-treating, and wet-etching;
l) an insulating film formed by evaporating silicon oxide or silicon nitride on the entire surface of the semiconductor substrate;
m) a barrier metal formed by forming an emitter contact window, a base contact window and a collector contact window by patterning the insulating film and the sinker protection film using a photo mask; cleaning the surface of the semiconductor substrate; and sputtering titanium (Ti) and titanium nitride (TiN); and
n) a base terminal, an emitter terminal, and a collector terminal provided by evaporating a conductive metal on the barrier metal, heat-treating and patterning.

26. The super self-aligned heterojunction bipolar transistor according to claim 25, wherein the sub-collector is formed by ion-implanting dopant with a concentration of about 5×10¹⁹ cm⁻³ into a portion of a semiconductor substrate and diffusing the dopant.

27. The super self-aligned heterojunction bipolar transistor according to claim 25, wherein the field insulating film is formed by performing a localized oxidation of silicon process (LOCOS) to oxidize the collector layer except the active collector region and the collector sinker.

28. The super self-aligned heterojunction bipolar transistor according to claim 27, wherein the collector layer is formed with a thickness of about 500 nm to about 1200 nm on the semiconductor substrate by a thermal oxidation method.

29. The super self-aligned heterojunction bipolar transistor according to claim 25, wherein the collector layer is formed with a thickness of about 500 nm to about 1200 nm on the semiconductor substrate by a thermal oxidation method.

30. The super self-aligned heterojunction bipolar transistor according to claim 25, wherein the sinker protection film is formed by ion-implanting dopant with a concentration of about 5×10¹⁹ cm⁻³ to about 1×10²⁰ cm⁻³ into the collector sinker, heat-treating, diffusing and removing a part of the upper surface of the collector sinker using a photo resist.

31. The super self-aligned heterojunction bipolar transistor according to claim 25, wherein the thermal oxidation film is a silicon oxide film formed with a thickness of about 20 nm to about 100 nm on the entire surface of the active collector region and the sinker protection film.

32. The super self-aligned heterojunction bipolar transistor according to claim 31, wherein the thermal oxidation film is a silicon oxide film, which is formed at a temperature of between about 900-1000° C.

33. The super self-aligned heterojunction bipolar transistor according to claim 25, wherein the thermal oxidation film is a silicon oxide film formed at a temperature of between about 900-1000° C.

34. The super self-aligned heterojunction bipolar transistor according to claim 25, wherein the base electrode is a polysilicon film with a thickness of about 200 nm to about 600 nm, which is formed by doping dopant having a concentration higher than about 1×10¹⁹ cm⁻³ into the entire surface of the thermal oxidation film by an in-situ process.

35. The super self-aligned heterojunction bipolar transistor according to claim 25, wherein the base electrode protection film is a silicon nitride film or a silicon oxide film evaporated on the base electrode with a thickness of about 200 nm to about 600 nm.

36. The super self-aligned heterojunction bipolar transistor according to claim 25, wherein the intrinsic collector is formed by exposing the base electrode and the base electrode protection film by dry-etching; wet-etching the thermal oxidation film using HF, NH₄F or a mixture thereof; ion-implanting dopant with a concentration of about 1×10¹⁶ cm⁻³ to about 5×10¹⁸ cm⁻³ into the active collector region; and heat-treating.

37. The super self-aligned heterojunction bipolar transistor according to claim 25, wherein the SiGe base layer is formed by growing in order a silicon film formed on the entire surface of the base electrode protection film, the intrinsic collector, and the sinker protection film, an undoped SiGe film, a SiGe film doped with p+ type dopant, and an undoped silicon film.

38. The super self-aligned heterojunction bipolar transistor according to claim 37, wherein the silicon film formed on the entire surface of the intrinsic collector and the sinker protection film has a thickness of about 10 nm to about 60 nm.

39. The super self-aligned heterojunction bipolar transistor according to claim 37, wherein the SiGe base layer has a thickness of about 50 nm to about 100 nm.

40. The super self-aligned heterojunction bipolar transistor according to claim 37, wherein the concentration of the Ge that forms the SiGe base layer ranges from about 1% to about 20%, and the doping concentration of the ion-implanted dopant ranges from about 5×10¹⁸ cm⁻³ to about 3×10²⁰ cm⁻³.

41. The super self-aligned heterojunction bipolar transistor according to claim 25, wherein the silicon film formed on the entire surface of the intrinsic collector and the sinker protection film has a thickness of about 10 nm to about 60 nm.

42. The super self-aligned heterojunction bipolar transistor according to claim 25, wherein the SiGe base layer has a thickness of about 50 nm to about 100 nm.

43. The super self-aligned heterojunction bipolar transistor according to claim 25, wherein the concentration of the Ge that forms the SiGe base layer ranges from about 1% to about 20% and the doping concentration of the ion-implanted dopant is ranges from about 5×10¹⁸ cm⁻³ to about 3×10²⁰ cm⁻³.

44. The super self-aligned heterojunction bipolar transistor according to claim 25, wherein the buffer protection film is a silicon oxide film formed on the entire surface of the SiGe base layer by a low pressure chemical vapor deposition (LPCVD) method.

45. The super self-aligned heterojunction bipolar transistor according to claim 25, wherein the buffer protection film is a silicon nitride film formed on the entire surface of the SiGe base layer by a low pressure chemical vapor deposition (LPCVD) method.

46. The super self-aligned heterojunction bipolar transistor according to claim 25, wherein the masking film is a silicon oxide film formed by dry-etching the buffer protection film so that the buffer protection film reaches the upper surface of the base electrode.

47. The super self-aligned heterojunction bipolar transistor according to claim 25, wherein the first sidewall film is a silicon oxide film or a silicon nitride film which is formed on the base layer, and wherein the base layer is exposed by removing the masking film by wet-etching.

48. The super self-aligned heterojunction bipolar transistor according to claim 47, wherein the first sidewall film is a silicon oxide film or a silicon nitride film with a thickness of about 50 nm to about 300 nm, and wherein the first sidewall film is formed on an exposed portion of the base layer by a low pressure chemical vapor deposition (LPCVD) method.

49. The super self-aligned heterojunction bipolar transistor according to claim 25, wherein the first sidewall film is a silicon oxide film or a silicon nitride film with a thickness of about 50 nm to about 300 nm, and wherein the is formed on an exposed portion of the base layer by a low pressure chemical vapor deposition (LPCVD) method.

50. The super self-aligned heterojunction bipolar transistor according to claim 25, wherein the second sidewall film is a silicon oxide film or a silicon nitride film with a thickness of about 200 nm to about 800 nm, wherein the second sidewall film is formed on the first sidewall film by a low pressure chemical vapor deposition (LPCVD) method.

51. The super self-aligned heterojunction bipolar transistor according to claim 25, wherein the emitter electrode is a polysilicon film which is formed by removing the second sidewall film by dry-etching; removing the first sidewall film by wet-etching; and evaporating on the base layer.

52. The super self-aligned heterojunction bipolar transistor according to claim 51, wherein the emitter electrode is a polysilicon film formed by removing the second sidewall film by dry-etching; removing the first sidewall film by wet-etching; and evaporating on an exposed portion of the base layer.

53. The super self-aligned heterojunction bipolar transistor according to claim 51, wherein the emitter electrode is formed by diffusing dopant contained in the polysilicon into the base layer; and patterning using a photo mask.

54. The super self-aligned heterojunction bipolar transistor according to claim 25, wherein the emitter electrode is a polysilicon film formed by removing the second sidewall film by dry-etching; removing the first sidewall film by wet-etching; and evaporating on an exposed portion of the base layer.

55. The super self-aligned heterojunction bipolar transistor according to claim 25, wherein the emitter electrode is formed by diffusing dopant contained in the polysilicon into the base layer; and patterning using a photo mask.

56. The super self-aligned heterojunction bipolar transistor according to claim 25, wherein the emitter sidewall film is a silicon nitride film or a silicon oxide film formed by removing the base electrode protection film by dry-etching; evaporating on the emitter electrode and the base electrode with a thickness of about 200 nm to about 1000 nm; and removing in a predetermined pattern by wet-etching.

57. The super self-aligned heterojunction bipolar transistor according to claim 25, wherein the ohmic electrode comprises titanium silicide (TiSi₂) wherein the ohmic electrode is formed by sputtering titanium (Ti) and titanium nitride (TiN) and heat-treating on the emitter electrode and the base electrode, and wherein the emitter electrode and the based electrode are exposed by wet-etching.

58. The super self-aligned heterojunction bipolar transistor according to claim 57, wherein the ohmic electrode is a titanium silicide (TiSi₂) with a thickness of about 40 nm to about 60 nm.

59. The super self-aligned heterojunction bipolar transistor according to claim 25, wherein the ohmic electrode comprises a titanium silicide (TiSi₂), and wherein the ohmic electrode has a thickness of about 40 nm to about 60 nm.

60. The super self-aligned heterojunction bipolar transistor according to claim 25, wherein the insulating film is a silicon oxide or a silicon nitride evaporated on the semiconductor substrate whereon the ohmic electrode is formed.

61. The super self-aligned heterojunction bipolar transistor according to claim 25, wherein the barrier metal is formed by patterning the insulating film and the sinker protection film to form an emitter contact window, a base contact window, and a collector contact window; cleaning the surface of the semiconductor substrate according to the standard cleaning process; and sputtering titanium (Ti) and titanium nitride (TiN).

62. The super self-aligned heterojunction bipolar transistor according to claim 25, wherein the conductive metal evaporated on the barrier metal is heat-treated and patterned so as to form a base terminal, an emitter terminal, and a collector terminal.

63. The super self-aligned heterojunction bipolar transistor according to claim 62, wherein the conductive metal evaporated on the barrier metal is selected from the group consisting of aluminium (Al), aluminium-silicon (Al—Si), copper (Cu) and gold (Au).

64. The super self-aligned heterojunction bipolar transistor according to claim 25, wherein the conductive metal evaporated on the barrier metal is selected from the group consisting of aluminium (Al), aluminium-silicon (Al—Si), copper (Cu) and gold (Au).
